(19) United States
(12) Patent Application Publication
(10) Pub. No.: US 2010/0190331 A1
(43) Pub. Date: Jul. 29, 2010

(54) System for Depositing a Film Onto a Substrate Using a Low Vapor Pressure Gas Precursor

(76) Inventors: Steven C. Selbrede, San Jose, CA (US); Martin Zucker, Orinda, CA (US); Vincent Venturo, Fremont, CA (US)

Correspondence Address: DORITY & MANNING, P.A., POST OFFICE BOX 1449, GREENVILLE, SC, 29602-1449, US

(21) Appl. No.: 12/559,928

(22) Filed: Sep. 15, 2009

Related U.S. Application Data
(62) Division of application No. 10/413,507, filed on Apr. 14, 2003, now abandoned.
(60) Provisional application No. 60/374,218, filed on Apr. 19, 2002.

(51) Int. Cl. H01L 21/443; C23C 16/06; C23C 16/18; C23C 16/44; H01L 21/469

(52) U.S. Cl. 438/608; 427/255.28; 427/255.32; 427/255.34; 427/255.37; 427/255.36; 438/780; 257/E21.478; 257/E21.487

(57) ABSTRACT

A method for depositing a film onto a substrate is provided. The substrate is contained within a reactor vessel at a pressure of from about 0.1 millitorr to about 100 millitorr. The method comprises subjecting the substrate to a reaction cycle comprising i) supplying to the reactor vessel a gas precursor at a temperature of from about 20° C. to about 150° C. and a vapor pressure of from about 0.1 torr to about 100 torr, wherein the gas precursor comprises at least one organo-metallic compound; and ii) supplying to the reactor vessel a purge gas, an oxidizing gas, or combinations thereof.

### RELATED APPLICATIONS

The present application claims is a divisional application of, claims priority to, and incorporates herein by reference U.S. patent application Ser. No. 10/413,507 filed on Apr. 14, 2003, which claims priority to Provisional Application Serial No. 60/374,218, filed on Apr. 19, 2002.

### BACKGROUND OF THE INVENTION

For forming advanced semiconductor devices, such as microprocessors and DRAMs (Dynamic Random Access Memories), it is often desired to form thin films on a silicon wafer or other substrate. Various techniques often used to deposit thin films onto a substrate include PVD (“Physical Vapor Deposition” or “sputtering”) and CVD (“Chemical Vapor Deposition”). Several types of CVD are often utilized, including APCVD (“Atmospheric Pressure CVD”), PECVD (“Plasma Enhanced CVD”), and LPCVD (“Low Pressure CVD”). LPCVD is typically a thermally activated chemical process (as distinguished from plasma-activated PECVD), and generally includes MOCVD (“Metal Organic CVD”) and ALD (“Atomic Layer Deposition”) as sub-categories.

One problem with many conventional films is that it is difficult to achieve the level of high capacitance or low leakage current desired for new advanced applications, such as memory cells, microprocessor gates, mobile phones, PDAs, and the like. As an example, silicon oxynitride (SiON) or a similar film is conventionally utilized as a dielectric for advanced gate applications. Silicon oxynitride has a dielectric constant “k” slightly above SiO₂ (k=4), and is generally created by a thermal oxidation and nitridation processes. Nevertheless, because the dielectric constant is relatively low, the capacitance of such a device can only be increased by decreasing the film thickness. Unfortunately, such a reduction in film thickness causes an increase in film defects and quantum mechanical tunneling, thereby leading to a high leakage current.

Thus, in order to provide a device with a higher capacitance but low leakage current, the use of a higher dielectric constant material has been proposed. For instance, materials such as tantalum pentoxide (Ta₂O₅) and aluminum oxide (Al₂O₃) have been proposed for use in memory cells. Similarly, materials such as zirconium oxide (ZrO₂) and hafnium oxide (HfO₂) have been proposed to replace silicon oxide and silicon oxynitride as microprocessor gates. To form thin films of such materials, it has been proposed that the materials be deposited using the conventional PVD and LPCVD techniques mentioned above.

However, although thin, high-k films can be deposited using PVD, such techniques are generally undesired due to their high cost, low throughput, and poor step conformality. The most promising techniques include ALD and MOCVD. For instance, ALD generally involves the sequential cycling of a precursor and oxidizer to the wafer surface to form a partial monolayer of film during each cycle. For example, as shown in FIG. 1, ALD of ZrO₂ using ZrCl₄ and H₂O starts with the flow of H₂O into the reactor to form an OH-terminated wafer surface (step “A”). After purging the H₂O from the reactor (step “B”), ZrCl₄ is flowed to react with the OH-terminated surface and forming a fraction of a ZrO₂ monolayer (step “C”). After the ZrCl₄ is purged from the reactor, the above cycle is repeated until the desired total film thickness is achieved.

The primary advantage of conventional ALD techniques is that the film growth is intrinsically self-limiting. In particular, only a fraction of a monolayer is deposited during each cycle with the fraction being determined by the inherent chemistry of the reaction (the amount of stearic hindrance), rather than by gas flow, wafer temperature, or other process conditions. Thus, uniform and repeatable films are generally expected for ALD.

Nevertheless, despites its advantages, conventional ALD techniques also possess a variety of problems. For instance, only a few precursors, generally metal halides, can be used in an ALD deposition process. Such precursors are generally solid at room temperature and thus difficult to deliver to the reactor. In fact, the precursor must often be heated to a high temperature and supplied in conjunction with a carrier gas to deliver sufficient precursor to the reactor. The use of a carrier gas method causes the deposition pressures to be generally high to ensure that the precursor concentration in the reactor is sufficient, which may limit the ability of the growing film to eject impurities during the purge or oxidation cycle steps. Also, a higher operating pressure may result in outgassing of precursor or oxidizer from walls and other surfaces during the “wrong” cycle step, resulting in less film control. Furthermore, flow repeatability can be a problem because the amount of precursor take-up depends sensitively on the precursor temperature and the amount of precursor remaining in the source bottle.

Another disadvantage of conventional ALD techniques is that metal halide precursors generally produce films with halide impurities, which may have a detrimental effect on the film properties. Also, some halides, such as chlorine, may create reactor or pump damage or environmental impacts. Still another disadvantage of conventional ALD techniques is that the deposition rate may be very low, because only a partial monolayer is deposited during each cycle, leading to low throughput and high cost of ownership. Finally, ALD metal precursors have a tendency to condense in the delivery lines and on reactor surfaces, leading to potential practical problems.

An alternative LPCVD deposition technique is MOCVD. In this method, an organic precursor, such as zirconium tert-butoxide (Zr[OC₄H₉]₄), may be used to deposit ZrO₂. This can be done by thermal decomposition of the zirconium tert-butoxide on the wafer surface, or oxygen may be added to ensure full oxidation of the precursor. One advantage of this method is that a wide variety of precursor choices are available. In fact, even traditional ALD precursors can be used. Some of these precursors are gases or liquids with vapor pressures that allow the precursors to be more easily delivered to the reactor. Another advantage of MOCVD is that the deposition is continuous (not cyclic), with higher deposition rates and lower cost of ownership.

However, a primary disadvantage of MOCVD is that deposition rate and film stoichiometry are not intrinsically self-limiting. In particular, film deposition rate is generally temperature and precursor flow rate dependent. Thus, wafer temperature must be very carefully controlled to achieve acceptable film thickness uniformity and repeatability. However, because MOCVD precursors are generally delivered by using a heated bubbler with a carrier gas, it is also usually difficult to control precursor flow with this technique. Another disadvantage of conventional MOCVD is that the process pressure is generally high, which may lead to potentially complex reactions with contaminants from reactor surfaces. Also, if the deposition rate is too high, impurities from the reactor or precursor (such as carbon) may be incorporated within the film.

As such, a need currently exists for an improved system of depositing a film onto a substrate.

### SUMMARY OF THE INVENTION

In accordance with one embodiment of the present invention, a method for depositing a film onto a substrate (e.g., semiconductor wafer) is disclosed. The substrate may be contained within a reactor vessel at a pressure of from about 0.1 millitorr to about 100 millitorr, and in some embodiments, from about 0.1 millitorr to about 10 millitorr, and also at a temperature of from about 100° C. to about 500° C., and in some embodiments, from about 250° C. to about 450° C.

The method comprises subjecting the substrate to a reaction cycle that comprises supplying to the reactor vessel a gas precursor at a temperature of from about 20° C. to about 150° C. and a vapor pressure of from about 0.1 torr to about 100 torr. In some embodiments, the gas precursor vapor pressure is from about 0.1 torr to about 10 torr, and the gas precursor temperature is from about 20° C. to about 80° C. The gas precursor comprises at least one organo-metallic compound, and may be supplied without the use of a carrier gas or bubbler. If desired, the flow rate of the gas precursor may be controlled (e.g., using a pressure-based controller) to enhance process repeatability.

Besides a gas precursor, the reaction cycle may also include supplying to the reactor vessel a purge gas, an oxidizing gas, or combinations thereof. For example, the purge gas may be selected from the group consisting of nitrogen, helium, argon, and combinations thereof. In addition, the oxidizing gas may be selected from the group consisting of nitric oxide, oxygen, ozone, nitrous oxide, steam, and combinations thereof.

As a result of the reaction cycle, at least a partial monolayer of a film is formed. For example, the film can contain a metal oxide that includes, but not limited to, aluminum oxide (Al₂O₃), tantalum oxide (Ta₂O₅), titanium oxide (TiO₂), zirconium oxide (ZrO₂), hafnium oxide (HfO₂), yttrium oxide (Y₂O₃), combinations thereof, and the like. In addition, the film can also contain a metal silicate, such as hafnium silicate or zirconium silicate. Additional reaction cycles may be used to achieve the target thickness (e.g., less than about 30 nanometers).

In accordance with another embodiment of the present invention, a low-pressure chemical vapor deposition system for depositing a film onto a substrate is disclosed. The system comprises a reactor vessel that includes a substrate holder for the substrate to be coated and a precursor oven adapted to supply a gas precursor to the reactor vessel at a temperature of from about 20° C. to about 150° C., and in some embodiments, from about 20° C. to about 80° C. The precursor oven may contain one or more heaters to heat the gas precursor to the desired temperature. The reactor vessel may contain multiple substrate holders for supporting multiple substrates.

The system further comprises a pressure-based controller capable of controlling the flow rate of the gas precursor supplied from the precursor oven so that it is supplied to the reactor vessel at a vapor pressure of from about 0.1 torr to about 100 torr, and in some embodiments, from about 0.1 torr to about 10 torr. The pressure-based controller may communicate with one or more valves. For instance, in one embodiment, the valves may be close-coupled to a reactor lid that separates the reactor vessel and precursor oven.

The system may also comprise a gas distribution assembly that receives the gas precursor from the precursor oven and delivers it to the reactor vessel. For example, the gas distribution assembly may include a showerhead that has a plenum. During a reaction cycle, the ratio defined by the pressure at the showerhead plenum divided by the pressure of the reactor vessel may be from about 1 to about 5, and in some embodiments, from about 2 to about 4.

Besides the components mentioned above, the system may also utilize various other components. For example, in one embodiment, the system may comprise a remote plasma generator in communication with the reactor vessel. In addition, the system may comprise an energy source capable of heating the substrate to a temperature of from about 100° C. to about 500° C., and in some embodiments, from about 250° C. to about 450° C.

Other features and aspects of the present invention are discussed in greater detail below.

### BRIEF DESCRIPTION OF THE DRAWINGS

A full and enabling disclosure of the present invention, including the best mode thereof, directed to one of ordinary skill in the art, is set forth more particularly in the remainder of the specification, which makes reference to the appended figures in which:

FIG. 1 is a graphical depiction of the flow rate and time period profiles of two reaction cycles for depositing ZrO₂ using the sequence, H₂O-purge-ZrCl₄-purge (A-B-C-B), in a conventional ALD process;

FIG. 2 is a graphical depiction of the flow rate and time period profiles of two reaction cycles for depositing an oxide film using the sequence, precursor-purge-oxidizer-purge (A-B-C-D), in accordance with one embodiment of the present invention;

FIG. 3 is an illustration of one embodiment of a system that may be used in the present invention;

FIG. 4 is an exemplary graphical illustration of the relationship between deposition thickness and deposition temperature for a non-ALD cyclic process and an ALD process;

FIG. 5 illustrates the backpressure model results for a 1 standard cubic centimeter per minute flow of hafnium (IV) t-butoxide in accordance with one embodiment of the present invention;

FIG. 6 illustrates the vapor pressure curve of hafnium (IV) t-butoxide in which the gas has a vapor pressure of 1 torr at 60° C. and 0.3 torr at 41° C.;

FIG. 7 illustrates the vapor pressure curve of HfCl₄ in which the gas has a vapor pressure of 1 torr at 172° C. and 0.3 torr at 152° C.

FIG. 8 illustrates one embodiment of a precursor oven that can be used in the present invention, in which FIG. 8a shows the layout of the precursor oven from an upper perspective and FIG. 8b shows the layout of the precursor oven from a lower perspective, illustrating the showerheads and reactor lid;

FIG. 9 illustrates one embodiment of a reactor vessel that can be used in the present invention; and

FIG. 10 is a schematic diagram of one embodiment of the system of the present invention illustrating gas flow and vacuum components.

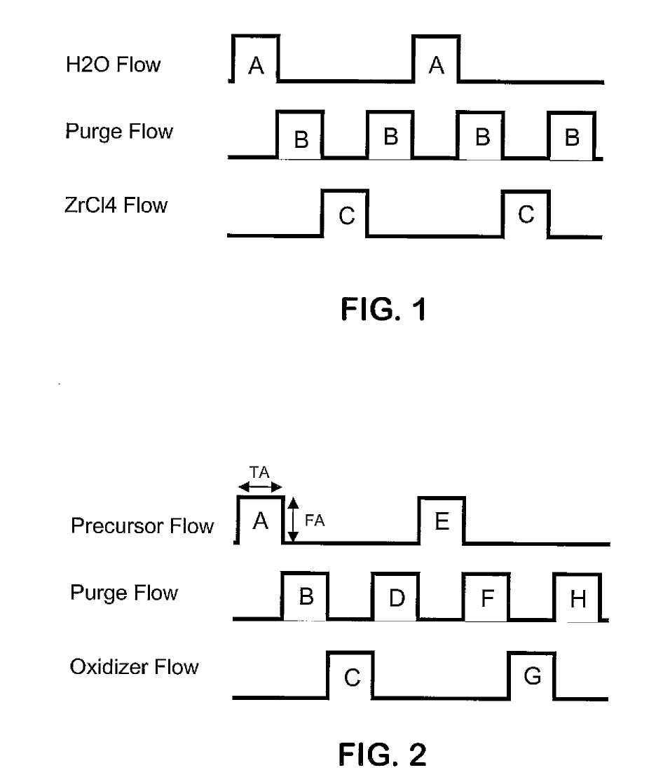

Repeat use of reference characters in the present specification and drawings is intended to represent same or analogous features or elements of the invention.

### DETAILED DESCRIPTION OF REPRESENTATIVE EMBODIMENTS

It is to be understood by one of ordinary skill in the art that the present discussion is a description of exemplary embodiments only, and is not intended as limiting the broader aspects of the present invention, which broader aspects are embodied in the exemplary construction.

The present invention is generally directed to a system and method for depositing a thin film onto a substrate. The film can generally have a thickness less than about 30 nanometers. For instance, when forming logic devices, such as MOSFET devices, the resulting thickness is typically from about 1 to about 8 nanometers, and in some embodiments, from about 1 to about 2 nanometers. Moreover, when forming memory devices, such as DRAMs, the resulting thickness is typically from about 2 to about 30 nanometers, and in some embodiments, from about 5 to about 10 nanometers. The dielectric constant of the film can also be relatively low (e.g., less than about 5) or high (greater than about 5) depending on the desired characteristics of the film. For instance, films formed according to the present invention might have a relatively high dielectric constant “k”, such as greater than about 8 (e.g., from about 8 to about 200), in some embodiments greater than about 10, and in some embodiments, greater than about 15.

The system of the present invention can be used to deposit a film that contains a metal oxide in which the metal is aluminum, hafnium, tantalum, titanium, zirconium, yttrium, silicon, combinations thereof, and the like. For instance, the system can be utilized to deposit a thin film of a metal oxide, such as aluminum oxide (Al₂O₃), tantalum oxide (Ta₂O₅), titanium oxide (TiO₂), zirconium oxide (ZrO₂), hafnium oxide (HfO₂), yttrium oxide (Y₂O₃), and the like, onto a semiconductor wafer made from silicon. Tantalum oxide, for example, typically forms a film having a dielectric constant between about 15 to about 30. Likewise, a metal silicate or aluminate compound, such as zirconium silicate (SiZrO₄), hafnium silicate (SiHfO₄), zirconium aluminate (ZrAlO₄), hafnium aluminate (HfAlO₄), and the like, can be deposited. Further, a nitrogen-containing compound, such as zirconium oxynitride (ZrON), hafnium oxynitride (HfON), and the like, can also be deposited. Moreover, other thin films can also be formed, including, but not limited to, dielectrics for gate and capacitor applications, metallic electrodes for gate applications, ferroelectric and piezoelectric films, conductive barriers and etch stops, tungsten seed layers, copper seed layers, and shallow trench isolation dielectrics and low-k dielectrics.

To deposit the film, the substrate can be subjected to one or more reaction cycles using a system of the present invention. For instance, in a typical reaction cycle, the substrate is heated to a certain temperature (e.g., from about 20° C. to about 500° C.). Thereafter, one or more reactive gas precursors are supplied to the reactor vessel in a cyclic manner. Additional reaction cycles can then be utilized to deposit other layer(s) onto the substrate to achieve a film with a desired thickness. As a result, a film can be formed in a reaction cycle that has a thickness equal to at least a partial monolayer.

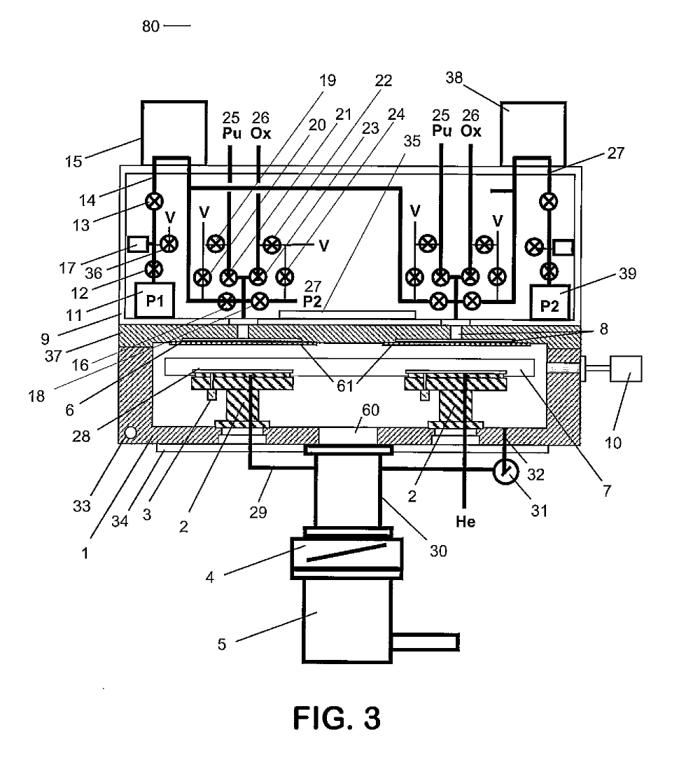

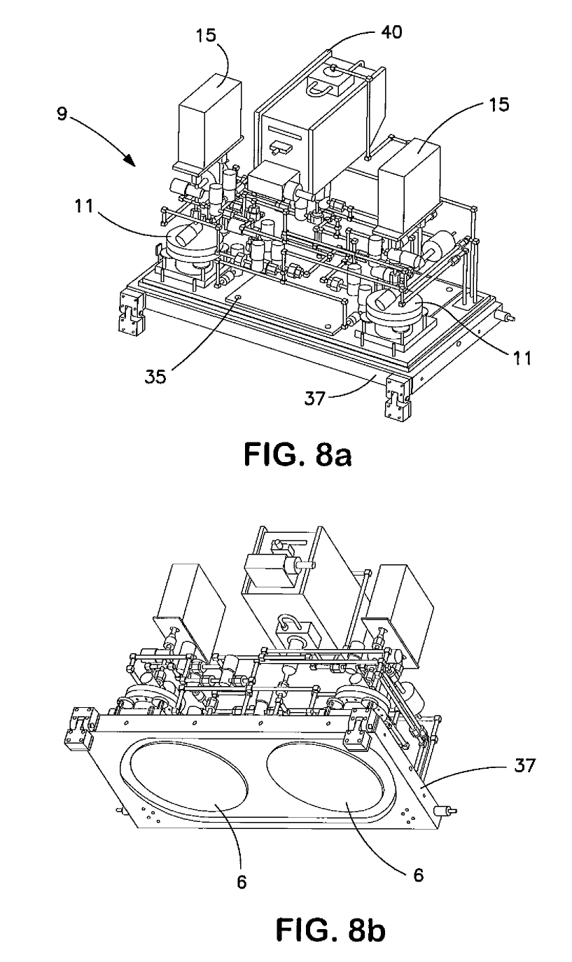

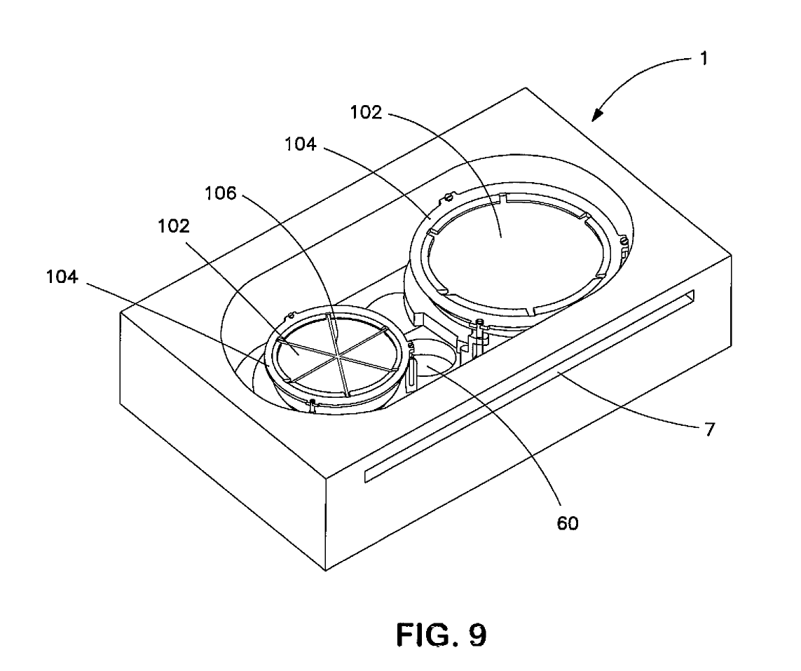

Referring to FIG. 3, for example, one embodiment of a system that can be used for the deposition of a film onto a substrate will now be described in more detail. It should be understood, however, that the system described and illustrated herein is merely one embodiment that can be used in the present invention, and that other embodiments are also contemplated in the present invention. In this regard, a system 80 is illustrated that generally includes a reactor vessel 1 (see also FIG. 9) and a precursor oven 9 separated by a reactor lid 37 (see also FIGS. 8a-8b). The reactor vessel 1 is adapted to receive one or more substrates, such as semiconductor wafers 28 and can be made from any of a variety of different materials, such as stainless steel, ceramic, aluminum, and the like. It should be understood, however, that besides wafers, the reactor vessel 1 is also adapted to process other substrates, such as optical parts, films, fibers, ribbons, etc.

The reactor vessel 1 may be provided with high vacuum (low pressure) during a reaction cycle. In the illustrated embodiment, the pressure within the reactor vessel 1 is monitored by a pressure gauge 10 and is controlled by a throttling gate valve 4. The low reactor vessel pressure can be achieved in a variety of ways. For example, in the illustrated embodiment, the low pressure is achieved using a vacuum pipe 30 and a turbomolecular pump 5 that communicates with a port 60 (see also FIG. 9). Of course, other techniques for achieving for the low pressure may also be used in the present invention. For instance, other pumps, such as cryopumps, diffusion pumps, mechanical pumps, and the like, may be used in conjunction with or in place of the turbomolecular pump 5. Optionally, the walls of the reactor vessel 1 may also be coated or plated with a material, such as nickel, that reduces wall outgassing while under vacuum pressure.

If desired, the temperature of the walls of the reactor vessel 1 may also be controlled during a reaction cycle (e.g., kept at a constant temperature) using a heating device 34 and/or a cooling passage 33. A temperature controller (not shown) can receive a temperature signal from a temperature-sensing device (e.g., thermocouple), and in response thereto, heat or cool the walls to the desired temperature if necessary.

The system 80 also includes two wafers 28 positioned on substrate holders 2. It should be understood, however, that any number of wafers 28 may be applied with a film using the system of the present invention. For instance, in one embodiment, a single wafer is supplied to the system 80 and applied with a film. In another embodiment, three or four wafers may be supplied to the system 80 and applied with a film. As shown, the wafers 28 can be loaded into the reactor vessel 1 through a reactor slit door 7 (see also FIG. 9).

Once positioned on the substrate holders 2, the wafers 28 may be clamped thereto using well-known techniques (e.g., mechanical and/or electrostatic). During a reaction cycle, the wafers 28 can be heated by heating devices (not shown) embedded within the substrate holders 2. For example, referring to FIG. 9, the reactor vessel 1 may contain two chucks 102 on which wafers may be disposed and clamped thereto with clamps 104. Alternatively, the wafers 28 may be heated by other well-known techniques used in the art, such as by lights, lasers (e.g., a nitrogen laser), ultraviolet radiation heating devices, arc lamps, flash lamps, infrared radiation devices, combinations thereof, and the like.

To facilitate thermal conduction between the wafers 28 and the substrate holders 2, a backside gas (e.g., helium) can be delivered to the backside of the wafers 28 via a gas delivery line 29. In the embodiment shown in FIG. 9, for instance, the chucks 102 may contain grooves 106 through which the helium may efficiently fill the space between the wafer 28 and the chucks 102. After being supplied, excess backside gas be diverted to a through-pipe 32. A pressure-based controller 31 can establish the pressure behind the wafer during diversion of the backside gas. Generally speaking, the amount of helium that leaks into the reactor vessel 1 is kept constant within a range of about 2 to about 20 standard cubic centimeters per minute.

Also positioned within the reactor vessel 1 are lift pins 3 that are configured to move the wafers 28 up from the substrate holders 2 so that a vacuum robot (not shown) can load and unload the wafers 28 into the reactor vessel 1 to begin a reaction cycle.

Besides the reactor vessel 1, the system 80 also includes a precursor oven 9 that is adapted to supply one or more gases to the reactor vessel 1 at a certain temperature and flow during a reaction cycle (see also FIGS. 8a-8b). Although not required, the precursor oven 9 can be formed from an insulating and heat resistant material, such as PVC plastic, Delrin, Teflon, and the like. In general, the oven 9 is in thermal communication with one or more heaters 35 that are configured to heat gases flowing therethrough and/or components within the oven 9 prior to and/or during a reaction cycle. A thermocouple can measure the temperature of the oven 9 and an external PID temperature controller, for instance, can adjust the power to the heater(s) 35 to maintain the desired temperature. In addition, one or more fans (not shown) may be enclosed within the precursor oven 9 to provide a more uniform temperature distribution throughout the oven 9.

In one embodiment, the precursor oven 9 contains at least one precursor supply 11 that provides one or more precursor gases to the reaction vessel 1. In this embodiment, a valve 12 isolates the precursor supply 11 so that the precursor supply 11 may be filled before installation into the precursor oven 9. To install the precursor supply 11 within the precursor oven 9, the precursor supply 11 is connected to a precursor delivery line 14. Thereafter, the delivery line 14 is pumped out and/or purged using a valve 36, Prior to deposition onto a substrate, the gas precursor can be heated by the heater(s) 35 to attain a certain vapor pressure. In some embodiments, for example, the gas precursor is maintained at a temperature of from about 20° C. to about 150° C. using a temperature-sensing device (e.g., thermocouple) and a temperature controller (not shown). For instance, a typical setpoint temperature for zirconium t-butoxide is from about 50° C. to about 75° C.

Upon being heated to the desired temperature, the gas precursor contained within the supply 11 can then be delivered to the reactor vessel 1 through the delivery line 14. Control over the flow of the gas precursor into the reactor vessel 1 is provided by the use of a valve 13, a pressure-based flow controller 15, and a valve 16. The conductance of the precursor gas delivery path from the supply 11 to the reactor vessel 1 can be maximized so that the backpressure is minimized, thus allowing for a minimum temperature of the precursor oven 9. For example, in one embodiment, the pressure-based flow controller 15 can utilize a pressure drop on the magnitude of 2 to 3 times for adequate pressure control, although other pressure drops can certainly be utilized. By utilizing a pressure-based controller 15 to control the flow rate of the gas precursor, the temperature control need not be as precise as with carrier gas or bubbler-type configurations.

The delivery line 14 supplies the precursor gas to two showerheads 61 that contain showerhead plates 6 and plenums 8, although any number of showerheads 61 may certainly be used in the present invention. The showerhead plates 6 possess holes for dispensing a gas onto the surface of the wafers 28. Although not required, the showerheads 61 are typically positioned from about 0.3 to about 5 inches from the upper surface of the wafers 28. The configuration and design of the holes in the showerheads 61 may be varied to support different chamber configurations and applications. In some embodiments, numerous small holes may be arranged in straight rows or in a honeycomb pattern with equal sized holes and equal distance between holes. In other embodiments, the density and size of holes may be varied to promote more uniform deposition. In addition, the holes may be angled directionally, or the showerhead may be titled to compensate for the gas flow of the particular chamber. Generally, the sizes, pattern and direction of the holes are selected to promote uniform deposition across the substrate surface given the configuration of the reactor vessel and other components.

As indicated above, a reactor lid 37 separates the precursor oven 9 from the reactor vessel 1. The reactor lid 37 is generally formed from aluminum or stainless steel and can keep the reactor vessel 1 from being exposed to air from the surrounding environment. In some embodiments, one or more of the valves used to control the flow of gases within the system 80 can be close-coupled to the reactor lid 37. Close-coupling allows the length of the gas delivery lines to be minimized so that vacuum conductance of the lines can be relatively high. High conductance lines and valves result in reduced backpressure from the showerheads to the precursor source vessels. For example, in one embodiment, the valves 16, 18 (discussed in more detail below), 21, and 23 are close-coupled to the reactor lid 37 so that the volume of the showerhead plenum 8 is minimized. In this embodiment, the volume of the showerhead plenum 8 includes the volume behind the showerhead faceplate 6, as well as the volume of the connecting lines up to the valve seats for the valves 16, 18, 21, and 23.

To form a film on the wafers 28, one or more gases are supplied to the reactor vessel 1. The film can be formed directly on the wafers 28 or on a barrier layer, such as a silicon nitride layer, previously formed on the wafers 28. In this regard, referring to FIGS. 2-3, one embodiment of the method of the present invention for forming a film on the wafers 28 will now be described in more detail. It should be understood, however, that other deposition techniques can also be used in the present invention.

As shown, a reaction cycle is initiated by first heating the wafers 28 to a certain temperature. The particular wafer temperature for a given reaction cycle can generally vary based on the wafer utilized, the gases utilized, and/or the desired characteristics of the deposited film, as will be explained in more detail below. For example, when depositing a dielectric layer onto a silicon wafer, the wafer temperature is typically maintained at from about 20° C. to about 500° C., in some embodiments, from about 100° C. to about 500° C., and in some embodiments, from about 250° C. to about 450° C. Moreover, the reactor vessel pressure during a reaction cycle can range from about 0.1 millitorr (“mtorr”) to about 100 mtorr, and in some embodiments, from about 0.1 mtorr to 10 mtorr. A low reactor vessel pressure can improve the removal of reaction impurities, such as hydrocarbon byproducts, from the deposited film and can help remove the precursor and oxidizing gas during the purge cycle(s). Typical ALD and MOCVD processes, on the other hand, usually operate at much higher pressures.

As illustrated by step “A” in FIG. 2, a gas precursor (illustrated as “P1” in FIG. 3) is supplied to the reactor vessel 1 while the wafers 28 are maintained at the wafer temperature via the line 14 for a time period “TA” and at a certain flow rate “FA”. In particular, the gas precursor is supplied to the reactor vessel 1 by opening the valves 12, 13 and 16, the flow being controlled by a pressure-based flow controller 15, such as a MKS Model 1150 or 1153 flow controller. Consequently, the gas precursor flows through the line 14, fills the showerhead plenum 8, and flows into the reactor vessel 1. If desired, the valves 19 and/or 22 can also be opened simultaneously to the opening of the gas precursor delivery valves 12, 13, and 16 to provide the flow of purge gas and oxidizing gas through the valves to the bypass pump. The simultaneous opening of the valves 19 and 22 can enable a stable flow of the purge and/or oxidizing gases to be established before such gases are delivered to the reactor vessel 1. The gas precursor flow rate “FA” can vary, but is typically from about 0.1 to about 10 standard cubic centimeters per minute, and in one embodiment, about 1 standard cubic centimeter per minute. The gas precursor time period “TA” can also vary, but is typically from about 0.1 to about 10 seconds or more, and in one embodiment, about 1 second. Upon contacting the heated wafers 28, the gas precursor chemisorbs, physisorbs, or otherwise reacts with the surface of the wafers 28.

In general, a variety of gas precursors can be utilized in the present invention to form the film. For example, some suitable gas precursors can include, but are not limited to, those gases that contain aluminum, hafnium, tantalum, titanium, silicon, yttrium, zirconium, combinations thereof, and the like. In some instances, the vapor of an organo-metallic compound can be used as the precursor. Some examples of such organo-metallic gas precursors can include, but are not limited to, tri-i-butylaluminum, aluminum ethoxide, aluminum acetylacetonate, hafnium (IV) t-butoxide, hafnium (IV) ethoxide, tetrabutoxysilane, tetraethoxysilane, pentakis(dimethylamino)tantalum, tantalum ethoxide, tantalum methoxide, tantalum tetraethoxyacetylacetonate, tetrakis(diethylamino)titanium, titanium t-butoxide, titanium ethoxide, tris(2,2,6,6-tetramethyl-3,5-heptanedionato)titanium, tris[N,N-bis(trimethylsilypamide]yttrium, tris(2,2,6,6-tetramethyl-3,5-heptanedionato)yttrium, tetrakis(diethylamino)zirconium, zirconium t-butoxide, tetrakis(2,2,6,6-tetramethyl-3,5-heptanedionato)zirconium, bis(cyclopentadienyl)dimethylzirconium, and the like. It should be understood, however, that inorganic metallic gas precursors may be utilized in conjunction with organic metallic precursors in the present invention. For example, in one embodiment, an organic metallic precursor (e.g., organo-silicon compound) is used during a first reaction cycle, while an inorganic metallic precursor (e.g., silicon-containing inorganic compound) is used during a second reaction cycle, or vice-versa.

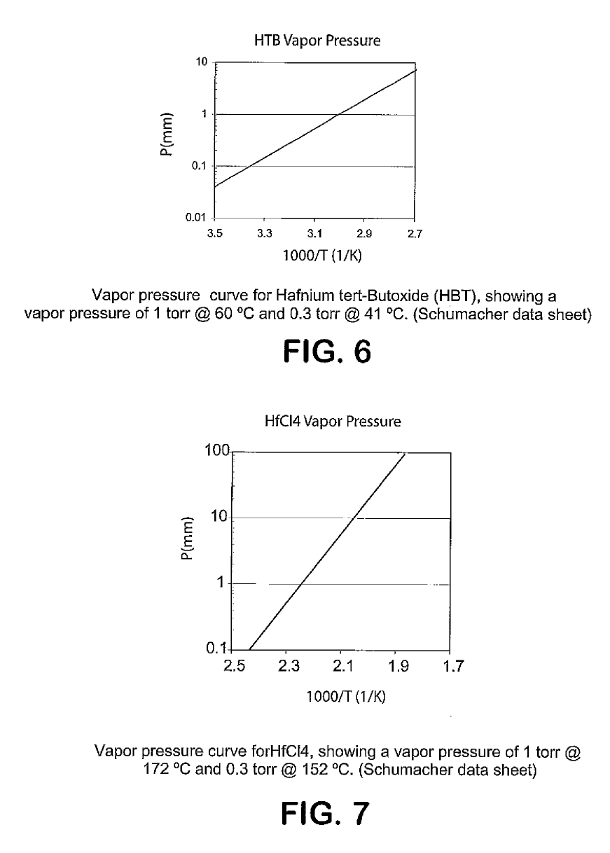

It has been discovered that organo-metallic gas precursors, such as described above, can be supplied to the reactor vessel 1 at a relatively low vapor pressure. The vapor pressure of the gas precursor can generally vary based on the temperature of the gas and the particular gas selected. However, in most embodiments, the vapor pressure of the gas precursor ranges from about 0.1 torr to about 100 torr, and in some embodiments, from about 0.1 torr to about 10 torr. A low pressure enables the pressure-based flow controller 15 to sufficiently control the pressure during a reaction cycle. Furthermore, such a low vapor pressure is also typically achieved at a relatively low gas precursor temperature. In particular, the gas precursor temperature during a reaction cycle is generally from about 20° C. to about 150° C., and in some embodiments, from about 20° C. to about 80° C. In this manner, the system of the present invention can utilize gases at a low pressure and temperature to enhance process efficiency. For example, FIG. 6 illustrates a vapor pressure curve for hafnium (IV) t-butoxide, in which the gas has a vapor pressure of 1 torr at 60° C. and 0.3 torr at 41° C. Thus, in this embodiment, a temperature of only about 41° C. would be required to achieve a vapor pressure of 0.3 torr. In contrast, precursor gases often used in conventional atomic layer deposition (ALD) processes, such as metal halides, generally require a much larger temperature to achieve such a low vapor pressure. For instance, FIG. 7 illustrates a vapor pressure curve for HfCl₄, in which the gas has a vapor pressure of 1 torr at 172° C. and 0.3 torr at 152° C. In this case, a temperature of at least about 152° C. would be required to achieve the same vapor pressure achieved for hafnium (IV) t-butoxide at a temperature of only about 41° C. Due to the difficulty in achieving a low vapor pressure using conventional ALD gas precursors, which is typically required for controllability, the gas precursors are often supplied with a carrier gas and/or used in conjunction with a bubbler. To the contrary, the gas precursors used in the present invention do not require such additional features, and are preferably supplied to the reactor vessel without a carrier gas and/or bubbler-type configuration.

After supplying the gas precursor (step “A” of FIG. 2), the valves 16 and 19 are closed (if open), and the valves 20 and 21 are opened (e.g., simultaneously). Thus, the gas precursor is diverted to a bypass pump, while a purge gas is directed from a delivery line 25 into the reactor vessel 1 through the showerhead plenum 8 at a certain flow rate “FB” and for a certain time period “TB” (step “B” of FIG. 2). Although not necessary, the flow rate “FB” and time period “TB” may approximate the flow rate “FA” and time period “TA”, respectively. During the supply of the purge gas, the residual gas precursor within the showerhead plenum 8 is gradually diluted and pushed into the reactor vessel 1 (i.e., purged from the showerhead plenum 8). Suitable purge gases may include, but are not limited to, nitrogen, helium, argon, and the like. Other suitable purge gases are described in U.S. Pat. No. 5,972,430 to DiMeo. Jr., which is incorporated herein in its entirety by reference thereto for all purposes.

The time required to accomplish the “purging” of the gas precursor generally depends on the volume of the showerhead plenum 8 and the backpressure of the showerhead. Therefore, the plenum volume and showerhead backpressure are generally tuned for the specific flow rates used in cycle step. Typically, the showerhead backpressure is tuned by adjusting the number of showerhead holes, the hole length, and/or the hole diameter until achieving a “backpressure ratio” of from about 1 to about 5, in some embodiments from about 2 to about 4, and in one embodiment, about 2. The “backpressure ratio” is defined as the plenum pressure divided by the reactor vessel pressure. Smaller ratios may be acceptable if flow uniformity is not critical. Likewise, higher ratios may also be acceptable, although the purge time and consequently cycle time may be increased, thereby reducing throughput. For example, FIG. 5 illustrates an embodiment in which hafnium (IV) tert-butoxide was supplied to a showerhead plenum at a flow rate of 1 standard cubic centimeter per minute. In this embodiment, the number of showerhead holes, hole length, and hole diameter were selected to achieve a chamber pressure (reactor pressure) of 1.0 millitorr and a showerhead plenum pressure of 2.4 millitorr. Accordingly, the “backpressure ratio” was 2.4. Further, in this embodiment, a hafnium (IV) t-butoxide vapor pressure of at least 300 millitorr would be required.

After supplying the purge gas to the reactor vessel 1 for the desired amount of time (step “B” of FIG. 2), the valves 21 and 22 are closed and the valves 19 and 23 are opened (e.g., simultaneously). This action diverts the purge gas to a bypass pump and directs an oxidizing gas from a delivery line 26 to the reactor vessel 1 through the showerhead plenum 8 at a certain flow rate “FC” and for a certain time period “TC” (step “C” of FIG. 2). Although not always required, the oxidizing gas may help to fully oxidize and/or densify the formed layer(s) to reduce the hydrocarbon defects present in the layer(s).

As described above, the showerhead plenum 8 and backpressure are generally tuned so that the oxidizing gas purges the previous gas from the plenum in a short time. To accomplish such purging, it is sometimes desired that the flow rate “FC” remain similar to the flow rates “FA” and/or “FB”. Likewise, the time period “TC” may also be similar to the time periods “TA” and/or “TB”. The time period “TC” may also be adjusted to achieve full oxidation of the growing film, but minimized to achieve best throughput. Suitable oxidizing gases can include, but are not limited to nitric oxide (NO₂), oxygen, ozone, nitrous oxide (N₂O), steam, combinations thereof, and the like.

During the time periods “TB” and/or “TC”, the wafers 28 can be maintained at a temperature that is the same or different than the temperature during gas precursor deposition. For example, the temperature utilized when applying the purge and/or oxidizing gases may be from about 20° C. to about 500° C., in some embodiments from about 100° C. to about 500° C., and in some embodiments, from about 250° C. to about 450° C. Further, as indicated above, the reactor vessel pressure is relatively low during the reaction cycle, such as from about 0.1 to about 100 millitorr, and from about 0.1 to about 10 millitorr.

Once the oxidizing gas has been supplied to the reactor vessel 1 (step “C” of FIG. 2), the valves 23 and 19 are closed and the valves 21 and 22 are opened (e.g., simultaneously). This action diverts the oxidizing gas to the bypass pump and again directs the purge gas to the reactor through the showerhead plenum 8 at a certain flow rate “FD” and a certain time period “TD”, which are typically the same as described above for step “B”.

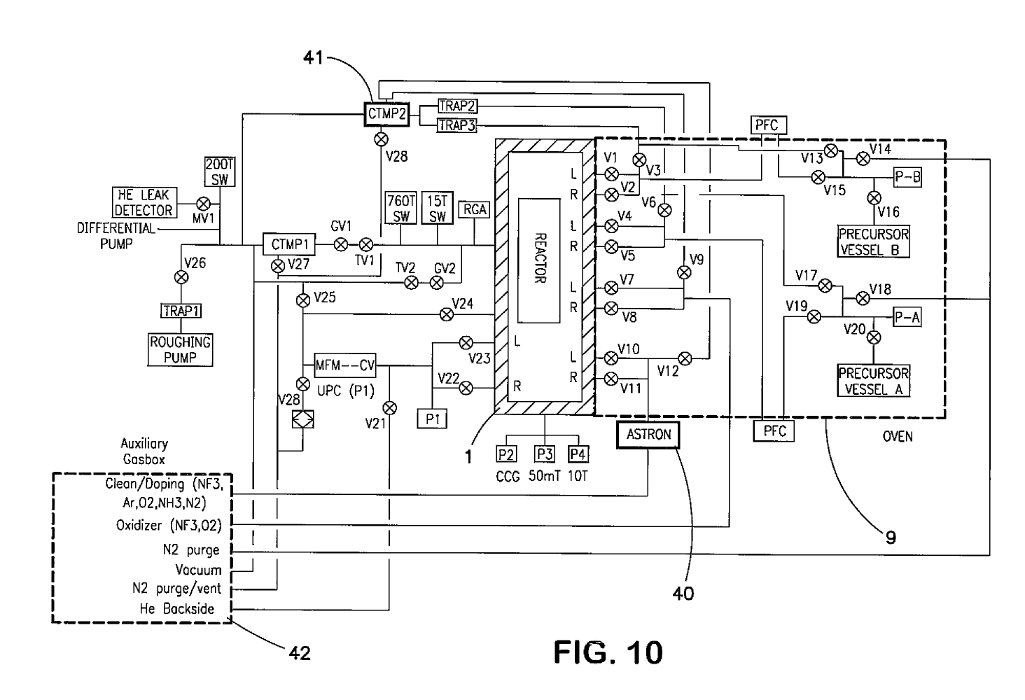

It should be noted that it is also possible to deliver atomic or excited states of the oxidizing and/or purge gases through the valves 21 and/or 23 and to the showerheads 61 for the purpose of assisting full oxidation of the growing film or for the purpose of doping the growing film with atoms. Referring to FIG. 10, for instance, a remote plasma generator 40 can be inserted between a gas box 42 and the precursor oven 9. The remote plasma generator 40 can also be used for cleaning the reactor of deposited films by using gases, such as NF₃. The gas box 42 can assist in providing such cleaning gases, as well as the gas precursor, purge gas, and/or oxidizing gases, to the precursor oven 9.

The aforementioned process steps are collectively referred to as a “reaction cycle”, although one or more of such steps of the “reaction cycle” may be eliminated if desired. A single reaction cycle generally deposits a fraction of a monolayer of thin film, but the cycle thickness may be several monolayers thick, depending on process conditions, such as wafer temperature, process pressure, and gas flow rates.

To achieve a target thickness, additional reaction cycles can be performed. Such additional reaction cycles may operate at the same or different conditions than the reaction cycle described above. For example, referring again to FIG. 3, a second precursor supply 39 can deliver a second precursor gas (illustrated as “P2”) through a second delivery line 27 and using a pressure-based flow controller 38. In this embodiment, a valve 18 isolates the precursor supply 39 so that the precursor supply 39 may be filled before installation into the precursor oven 9. The precursor supply 39 can be installed in a manner similar to precursor supply 11. Prior to deposition onto a substrate, the gas precursor from supply 39 can also be heated by the heater(s) 35 to attain a certain vapor pressure.

The reaction cycle for the second precursor may be similar to or different than the reaction cycle for the first precursor as described above. In one particular embodiment, for instance, additional steps “E-H” (FIG. 2) may be used to produce an alternating laminate of first and second gas precursor films in a single reaction cycle. For each cycle, the precursor gases (“E” and “A”), the purge gases (“B”, “D”, “F”, and “H”), and the oxidizing gases (“C” and “G”) may be the same or different. Alternatively, the first gas precursor film can also be deposited to a specific thickness (one or multiple reaction cycles), followed by the second gas precursor film to another specific thickness (one or multiple reaction cycles), thus building a “stacked” structure of films. For example, a laminate of HfO₂ and SiO₂ could be created by using hafnium (IV) t-butoxide as the first gas precursor and silane as the second gas precursor, which after annealing, can produce a hafnium silicate film. Another example is the formation of a laminate of HfO₂ and Al₂O₃ by using hafnium (IV) t-butoxide as the first gas precursor and aluminum ethoxide as the second gas precursor, which after annealing, can produce a hafnium acuminate film. Further, another example is the formation of a hafnium-silicon-nitrogen-oxygen film by using appropriate multiple precursors and other process conditions.

The deposition of laminate films, such as described above, can be subsequently followed by appropriate thermal processing such that a “new” film can be produced with properties different from either the laminate film or the laminate constituents themselves. For example, a “new” hafnium silicate film could be formed by thermally annealing a laminate of hafnium oxide and silicon oxide. Further, a laminate of HfO₂ and HfON films could be formed by using hafnium (IV) t-butoxide and NH₃, which after annealing, produces a hafnium oxynitride film. It is also noted that a laminate can be formed using a system of the present invention in conjunction with other conventional techniques, such as ALD, MOCVD, or other techniques.

In accordance with the present invention, various parameters of the method described above may be controlled in order to produce a film having certain preselected characteristics. For example, as indicated above, the gas precursor, purge, and/or oxidizing gases used in the reaction cycles may be selected to be the same or different. Moreover, in one embodiment, the “deposition conditions” (i.e., conditions for the time period in which a gas is allowed to contact the substrate) of one or more the reaction cycles can be controlled. In some embodiments, for instance, it may be desired to utilize a certain preselected pressure profile, deposition time period profile, and/or flow rate profile so that one reaction cycle operates at one set of deposition conditions, while another reaction cycle operates at another set of deposition conditions.

As a result of controlling various parameters of one or more of the reaction cycles, the present invention can achieve a variety of benefits. For instance, in contrast to conventional ALD techniques, the system of the present invention can have a higher yield and sufficiently inhibit leakage current. Moreover, by providing control of the cycle parameters, the resulting film can be more easily formed to have selected properties. These properties can be instantaneously adjusted when desired by simply altering one of the cycle parameters, such as the flow rate of a gas being supplied. Moreover, some layers of the film can be formed to have one characteristic, while other layers can be formed to have another characteristic. Therefore, in contrast to conventional deposition techniques, the system of the present invention provides control over the reaction cycle parameters so that the resulting film can be more readily formed to have specific, predetermined properties.

In addition, it has also been discovered that, in contrast to conventional traditional ALD techniques, the thickness obtained during a reaction cycle is not intrinsically limited by steric hindrance of the surface chemistry. Thus, the reaction cycle is not limited to a fixed fraction of a monolayer of film deposited for each cycle, but can be decreased for improved film control or increased for throughput improvement. For instance, the cycle thickness of a film can be adjusted by controlling various system conditions, such as wafer temperature, gas flow rates, reactor vessel pressure, and gas flow time periods. Adjustment of these parameters can also optimize the characteristics of the resulting film. As an example, the thickness deposited during each reaction cycle could be increased to a maximum value in order to achieve high wafer throughput, while simultaneously achieving acceptable film properties, such as stoichiometry, defect density, and impurity concentration.

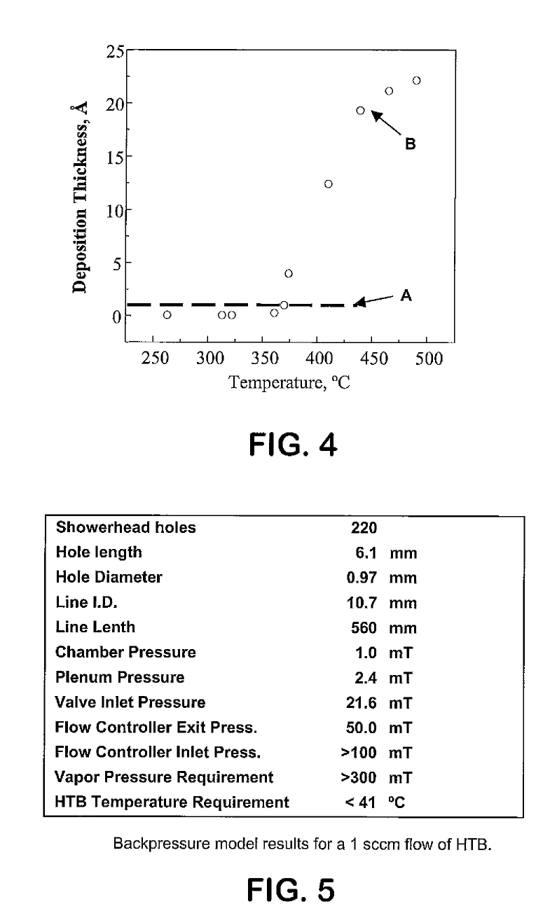

Referring to FIG. 4, for instance, the relationship between film thickness and wafer temperature is illustrated for an ALD cyclic process (curve A) and for a non-ALD process (curve B). For a non-ALD cyclic process, such as used in the present invention, the deposition thickness for a wafer temperature of about 370° C. is about 1 Angstrom (Å) per reaction cycle in this illustration. If the wafer temperature is increased to about 375° C., the deposition thickness is about 4 Å per reaction cycle. In contrast, for an ALD process (curve A), film thickness is relatively independent of wafer temperature.

Thus, in contrast to conventional ALD techniques, the method of the present invention can be used to form multiple oxide monolayers in a single reaction cycle. Moreover, the layers formed in accordance with the present invention can be fully oxidized in incremental steps, i.e., between deposition of gas precursors in different reaction cycles. Also, in contrast to conventional ALD techniques, composite or laminate films can easily be deposited due to the wide availability of suitable MOCVD precursors.

Moreover, the cyclic nature of the system of the present invention can actually enhance the removal of impurities (e.g., hydrocarbon byproducts) formed during a reaction cycle. Specifically, by depositing only a small thickness of film during each cycle, the purging and oxidation steps can more easily remove impurities. Conventional MOCVD processes, on the other hand, grow films continuously, which makes impurity removal more difficult.

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A method for depositing a film onto a substrate, the substrate being contained within a reactor vessel at a pressure of from about 0.1 millitorr to about 100 millitorr, said method comprising subjecting the substrate to a reaction cycle comprising:
i) supplying to the reactor vessel a gas precursor at a temperature of from about 20° C. to about 150° C. and a vapor pressure of from about 0.1 torr to about 100 torr, wherein said gas precursor comprises at least one organo-metallic compound; and
ii) supplying to the reactor vessel a purge gas, an oxidizing gas, or combinations thereof.

2. A method as defined in claim 1, wherein the pressure of reactor vessel is at from about 0.1 millitorr to about 10 millitorr.

3. A method as defined in claim 1, wherein the substrate is at a temperature of from about 100° C. to about 500° C.

4. A method as defined in claim 1, wherein the substrate is at a temperature of from about 250° C. to about 450° C.

5. A method as defined in claim 1, wherein said gas precursor is supplied without a carrier gas or bubbler.

6. A method as defined in claim 1, wherein said gas precursor consists of said at least one organo-metallic compound.

7. A method as defined in claim 1, further comprising controlling the flow rate of said gas precursor.

8. A method as defined in claim 1, wherein said gas precursor vapor pressure is from about 0.1 torr to about 10 torr.

9. A method as defined in claim 1, wherein said gas precursor temperature is from about 20° C. to about 80° C.

10. A method as defined in claim 1, wherein said purge gas is selected from the group consisting of nitrogen, helium, argon, and combinations thereof.

11. A method as defined in claim 1, wherein said oxidizing gas is selected from the group consisting of nitric oxide, oxygen, ozone, nitrous oxide, steam, and combinations thereof.

12. A method as defined in claim 1, wherein the film contains a metal oxide, wherein said metal of said metal oxide film is selected from the group consisting of aluminum, tantalum, titanium, zirconium, silicon, hafnium, yttrium, and combinations thereof.

13. A method as defined in claim 1, wherein the film has a dielectric constant greater than about 8.

14. A method as defined in claim 1, further comprising subjecting the substrate to one or more additional reaction cycles to achieve a target thickness.

15. A method as defined in claim 14, wherein said target thickness is less than about 30 nanometers.

16. A method for depositing a film onto a semiconductor wafer, the wafer being contained within a reactor vessel at a pressure of from about 0.1 millitorr to about 100 millitorr and at a temperature of from about 20° C. to about 500° C., said method comprising subjecting the wafer to a reaction cycle comprising:
i) supplying to the reactor vessel a gas precursor at a temperature of from about 20° C. to about 150° C. and a vapor pressure of from about 0.1 torr to about 100 torr, wherein said gas precursor comprises at least one organo-metallic compound; and
ii) supplying to the reactor vessel a purge gas; and
iii) thereafter, supplying to the reactor vessel an oxidizing gas.

17. A method as defined in claim 16, wherein the pressure of the reactor vessel is at from about 0.1 millitorr to about 10 millitorr.

18. A method as defined in claim 16, wherein the wafer is at a temperature of from about 250° C. to about 450° C.

19. A method as defined in claim 16, wherein said gas precursor is supplied without a carrier gas or bubbler.

20. A method as defined in claim 16, wherein said gas precursor consists of said at least one organo-metallic compound.
